(19) United States
(12) Patent Application Publication
(10) Pub. No.: US 2010/0252940 A1
(43) Pub. Date: Oct. 7, 2010

(54) POLYIMIDE SHIELD AND INTEGRATED CIRCUIT STRUCTURE HAVING THE SAME

(75) Inventors: Tang-Chieh HUANG, Tainan County (TW); Chau-Chin CHUANG, Kaohsiung City (TW); Szu-Hsiang SU, Tainan County (TW)

Correspondence Address: PEPPER HAMILTON LLP, ONE MELLON CENTER, 50TH FLOOR, 500 GRANT STREET, PITTSBURGH, PA, 15219, US

(73) Assignee: MICROCOSM TECHNOLOGY CO., LTD., Tainan County (TW)

(21) Appl. No.: 12/718,930

(22) Filed: Mar. 5, 2010

(30) Foreign Application Priority Data
Apr. 1, 2009 (TW) 098110872

(51) Int. Cl. H01L 23/29; H01L 27/14; B05D 5/12; B32B 27/34; B32B 27/18

(52) U.S. Cl. 257/792; 428/473.5; 428/339; 428/354; 428/41.6; 427/77; 257/E23.116

(57) ABSTRACT

A polyimide shield includes a base film layer that is made from polyimide, and a colored film layer that overlies the base film layer and that contains a coloring agent dispersed in a polymer. A method of making the polyimide shield includes forming the base film layer from polyimide and applying a liquid composition onto the base film layer. The liquid composition contains a polymer and the coloring agent that is dispersed in the polymer. An integrated circuit structure includes a circuitry substrate and the polyimide shield that covers the circuitry substrate.

### CROSS-REFERENCE TO RELATED APPLICATION

This application claims priority of Taiwanese application no. 098110872, filed on Apr. 1, 2009.

### BACKGROUND OF THE INVENTION

1. Field of the Invention

This invention relates to a shield, more particularly to a polyimide shield, a method of making the polyimide shield, and an integrated circuit structure that has the polyimide shield.

2. Description of the Related Art

Referring to FIG. 1, a conventional shield 2 covers a circuit system 1 of a circuit board for protecting the circuit system 1 from oxidation. The shield 2 includes an adhesive film layer 21 that is attached to the circuit system 1 and a shielding film layer 22 that is immobilized on the circuit system 1 through the adhesive film layer 21. Since polyimide has a good insulating ability, heat resistance, and chemical resistance, the shielding film layer 22 is commonly made from polyimide, and is consequently transparent and yellow. In order to prevent a negative visual effect arising from the complicated circuit system 1 and divulgence of technology for the circuit system 1, the shielding film layer 22 has been developed so as to have colors, particularly black and white.

Referring to FIG. 2, a shielding film layer 22′ of another conventional shield 2′ is colored and is able to shield a complicated circuit system 1′. A method of making the colored shielding film layer 22′ is described as follows. A desired coloring agent 22′1 is selected so that the shielding film layer 22′ can be formed with a desired color. For example, a white coloring agent (such as titanium oxide) or a black coloring agent (such as carbon black) can be used. Afterward, the coloring agent 22′1 and a suitable polymer 22′2 such as commonly used polyimide) are mixed together, thereby forming the shielding film layer 22′ that has the desired color and that is able to shield the circuit system 1′. Related skills are disclosed in U.S. Pat. No. 5,031,017 and U.S. Pat. No. 5,078,936.

However, the mixing of the coloring agent 22′1 and the polymer 22′2 lowers properties (e.g., mechanical properties, electrical properties, etc.) of the shielding film layer 22′ compared to the conventional shielding film layer 22 that is simply made from a polymer. For instance, in U.S. Pat. No. 5,078,936, polyimide is mixed with carbon black to form a black polyimide article, and volume resistivity of the polyimide article decreases when am amount of carbon black in the polyimide article increases. Consequently, maintaining sufficient volume resistivity and other physical properties becomes a problem. When an amount of the coloring agent 22′1 is reduced in the shielding film layer 22′ so that the shield 2′ has physical properties capable of meeting requirements in the market, the shield 2′ is unable to efficiently shield the circuit system 1′. Thus, simultaneously maintaining the physical properties and the shielding ability of the shield 2′ is problematic. Furthermore, a high production cost of the inefficient shield 2′ leads to a high production cost of an article employing the shield 2′.

### SUMMARY OF THE INVENTION

Therefore, the object of the present invention is to provide a polyimide shield that can overcome the aforesaid drawbacks of the prior art, a method of making the polyimide shield, and an integrated circuit structure that has the polyimide shield.

According to one aspect of this invention, a polyimide shield includes a base film layer that is made from polyimide, and a colored film layer that overlies the base film layer and that contains a coloring agent dispersed in a polymer.

According to another aspect of this invention, a method of making a polyimide shield includes forming a base film layer from polyimide, and applying a liquid composition onto the base film layer. The liquid composition contains a polymer and a coloring agent that is dispersed in the polymer.

According to yet another aspect of this invention, an integrated circuit structure includes a circuitry substrate and a polyimide shield that covers the circuitry substrate. The polyimide shield includes a base film layer that is made from polyimide, and a colored film layer that overlies the base film layer and that contains a coloring agent dispersed in a polymer.

### BRIEF DESCRIPTION OF THE DRAWINGS

Other features and advantages of the present invention will become apparent in the following detailed description of the preferred embodiments of this invention, with reference to the accompanying drawings, in which:

FIG. 1 is a fragmentary partly sectional view of a conventional shield covering a circuit system;

FIG. 2 is a fragmentary schematic partly sectional view of another conventional shield covering a circuit system;

FIG. 3 is a schematic diagram of the first preferred embodiment of a polyimide shield according to this invention;

FIG. 4 is a fragmentary schematic partly sectional view illustrating that the second preferred embodiment of the polyimide shield covers a circuitry substrate according to this invention;

FIG. 5 is a schematic diagram of the third preferred embodiment of the polyimide shield according to this invention; and

FIG. 6 is a fragmentary schematic partly sectional view illustrating that the first preferred embodiment of the polyimide shield covers a circuitry substrate.

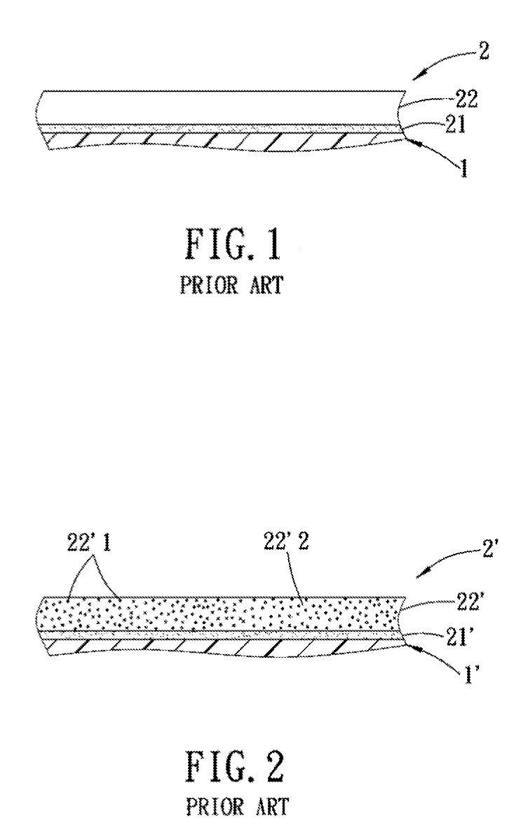

### DETAILED DESCRIPTION OF THE PREFERRED EMBODIMENTS

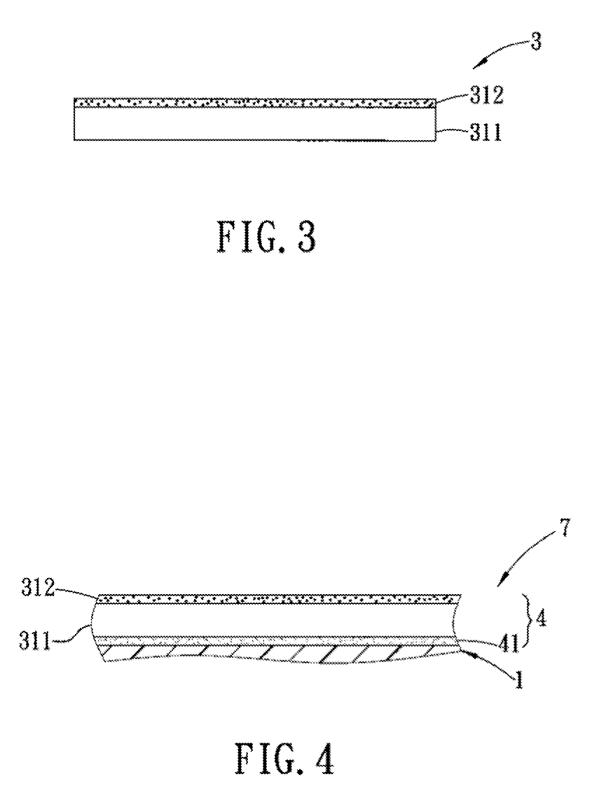

Before the present invention is described in greater detail, it should be noted that same reference numerals have been used to denote like elements throughout the specification, and that FIGS. 3, 4, 5, and 6 are not drawn to scale for the sake of convenience.

Referring to FIG. 3, the first preferred embodiment of a polyimide shield 3 according to the present invention includes a base film layer 311 that is made from polyimide, and a colored film layer 312 that overlies the base film layer 311. The colored film layer 312 has a shielding ability, and contains a polymer and a coloring agent that is dispersed in the polymer.

Referring to FIG. 4, the second preferred embodiment of the polyimide shield 4 according to the present invention is similar to the first preferred embodiment except that the polyimide shield 4 further includes an adhesive film layer 41 formed on the base film layer 311 opposite to the colored film layer 312. In this embodiment, the polyimide shield 4 is attached to a circuitry substrate 1 by virtue of the adhesive film layer 41 so as to form an integrated circuit structure 7.

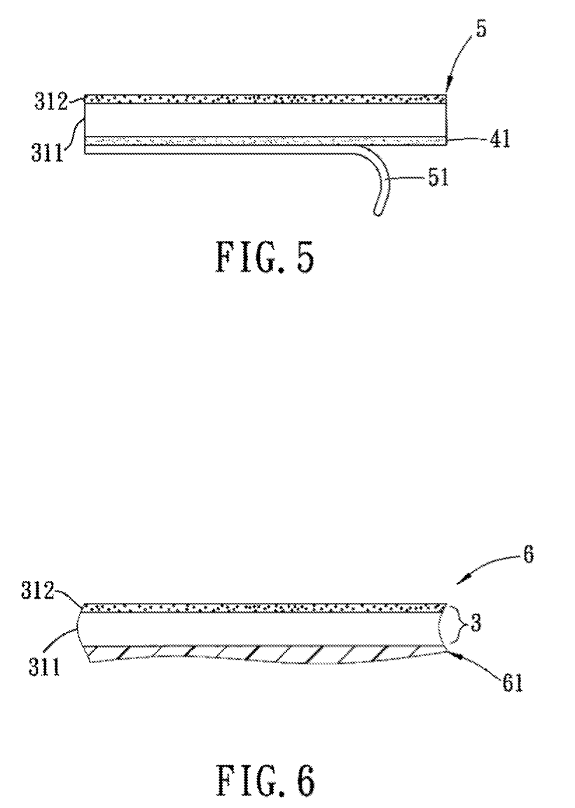

Referring to FIG. 5, the third preferred embodiment of the polyimide shield 5 according to the present invention is similar to the second preferred embodiment except that the polyimide shield 5 further includes a release film layer 51 covering the adhesive film layer 91 and removable from the same.

Preferably, the colored film layer 312 has a light transmittance less than 1%. The polymer is selected from the group consisting of polyimides, aromatic polyamides, aromatic poly(amide-imides), aromatic poly(1,3,4-oxadiazoles), aromatic polyhydrazides, and aromatic polyetherimides. In order to reduce differences between the characteristics of the materials of the base film layer 311 and the colored film layer 312, polyimide is used as the polymer in the colored film layer 312.

The ratio of the polymer to the coloring agent can be adjusted so as to provide the colored film layer 312 with brightness or haze effect. When smaller amount of the coloring agent is utilized, the shielding ability of the polyimide shield 3,4,5 is lower, and the colored film layer 312 is brighter. On the other hand, when larger amount of the coloring agent is used, the colored film layer 312 has more haze effect. Preferably, the weight ratio of the polymer to the coloring agent ranges from 1-10. More preferably, the weight ratio of the polymer to the coloring agent ranges from 1.5-8.

The coloring agent used in the invention refers to one which can provide the colored film layer 312 with a desired color and a shielding effect. The coloring agent should be stable at 400° C. Preferably, the coloring agent is selected from the group consisting of carbon black (for a black color), titanium oxide (for a white color), boron nitride (for a white color), aluminum nitride (for a white color), and combinations thereof. When different compounds are mixed to form the coloring agent, the color of the colored film layer 312 is a mixed color of the different compounds. For instance, when titanium oxide and carbon black are mixed to form the coloring agent, the colored film layer 312 has a gray color. Preferably, the colored film layer 312 is black or white so as to meet requirements of the electronic product manufacturers.

When a thickness of the colored film layer 312 is larger, the polyimide shield 3,4,5 has better shielding ability. However, the larger the thickness of the colored film layer 312, the weaker the bonding between the colored film layer 312 and the base film layer 311 will be. Preferably, the colored film layer 312 has the thickness ranging from 1 μm-3 μm. More preferably, the colored film layer 312 has the thickness ranging from 2 μm-2.5 μm.

According to the present invention, the preferred embodiment of a method of making the polyimide shield 3 is described as follows. Firstly, the base film layer 311 is formed from polyimide. A liquid composition is applied onto the base film layer 311 and is solidified by virtue of a curing process, thereby forming the colored film layer 312. The liquid composition contains a polymer and the coloring agent dispersed in the polymer.

Polyimide for forming the base film layer 311 is commercially available in the market. When the polymer in the liquid composition is in a solid form, the liquid composition may further contain a solvent for dissolving the polymer therein. Preferably, the polymer in the liquid composition is selected from the group consisting of polyimide and polyamic acid. Polyamic acid is a precursor of polyimide and can be cyclized to form polyimide through a curing process of the liquid composition. Preferably, the liquid composition has a viscosity of 200 cps-3000 cps. More preferably, the liquid composition has a viscosity of 500 cps-1000 cps.

### EXAMPLES

### Materials

1. P-phenylenediamine (ACROS, product no. 130575000)
2. 4,4′-oxydianiline (ACROS, product no. 104335000)
3. N-methyl-2-pyrrolidone (MERCK, product no. TN3001)
4. Promellitic dianhydride (ACROS, product no. 105325000)
5. Carbon black (DEGUSSA, product no. FW 200)
6. 1,4-bis(4-aminophenoxy)benzene (TCI, product no. B1243)
7. 4,4′-(hexafluoroisopropylidene)diphthalic anhydride (TCI, product no. H0771)
8. Xylene (ECHO, product no. XA-2101)
9. Titanium oxide (ISK, product no. TTO-55S)
10. Diphenyl-3,3′,4,4′-tetracarboxylic dianhydride (TCI, product no. 81326)

### Formation of Polyimide Base Film Layer

### Example A

7.56 g of p-phenylenediamine and 6 g of 4,4′-oxydianiline were dissolved in 172 g of N-methyl-2-pyrrolidone (MP) to form a solution. 29 g of promellitic dianhydride was subsequently added into the solution. Reaction of the aforementioned chemicals proceeded for 24 hours at 25° C. such that polyamic acid having a viscosity of about 50000 cps was formed. Polyamic acid was applied onto a copper foil, and was sequentially heated for 6 minutes at 160° C. and for 60 minutes at 350° C. Therefore, polyamic acid was cyclized to form the polyimide base film layer 311 having a thickness of 25 μm. The polyimide base film layer 311 was removed from the copper foil.

### Production of Polyimide Shield

### Example 1B

1 g of p-phenylenediamine and 2 g of 4, 4′-oxydianiline were dissolved in 70 g of NMP to form a solution. 5.9 g of promellitic dianhydride was added into the solution. Reaction of the aforementioned chemicals proceeded for 24 hours at 25° C., thereby forming polyamic acid that had a viscosity of about 2000 cps.

25 wt % of carbon black was added to polyamic acid based on 100 weight percent of polyamic acid and was uniformly dispersed so as to form the liquid composition that had 20 wt % of carbon black. The liquid composition was subsequently applied onto the aforementioned polyimide base film layer 311. A solidification process was carried out to sequentially preheat the liquid composition at 160° C. and heat the same at. 300° C. such that polyamic acid in the liquid composition was cyclized to form polyimide. The colored film layer 312 was formed, and had the thickness of 2 μm and a black color. Thus, the polyimide shield 3 was produced.

### Example 2B

5.8 g of 1,4-bis(4-aminophenoxy)benzene and 112 g of NMP were mixed and stirred. After 1,4-bis(4-aminophenoxy)benzene was dissolved in NMP to from a solution, 8.82 of 4,4′-(hexafluoroisopropylidene)diphthalic anhydride was added into the solution. Reaction of the aforementioned chemicals proceeded 24 hours at 25° C., thereby forming polyamic acid. Xylene as an azeotropic agent was added to polyamic acid, and a temperature of the reactants was increased to 180° C. After 24 hours, a polyimide solution having a viscosity of about 1500 cps was formed. Carbon black was added into the polyimide solution until 20% by weight of carbon black was contained in the polyimide solution. Subsequently, the polyimide solution was applied onto the aforementioned polyimide base film layer 311 and was solidified at 200° C. The colored film layer 312 was formed, and had the thickness of 2 μm and a black color. Therefore, the polyimide shield 3 was completed.

### Example 3B

A polyimide solution that had a viscosity of about 1500 cps was produced by virtue of the method for Example 2B. White titanium oxide was added into and uniformly dispersed in the polyimide solution to form the liquid composition until the liquid composition had 50% by weight of titanium oxide. The liquid composition was applied onto the aforementioned polyimide base film layer 311, and a solidification process was conducted at 200° C. Consequently, NMP was evaporated, and the colored film layer 312 that had a thickness of 2 μm and a white color was formed. Accordingly, the polyimide shield 3 was made.

### Comparative Example

A liquid composition containing polyamic acid and carbon black was formed by dint of the method of forming the liquid composition for Example 1B, and was used to produce a shield via the solidification process for Example 1B. The shield had a thickness equal to those of Examples 1B and 2B.

### Comparison Between Example 1B and Comparative Example

Mechanical properties of Example 1B and Comparative example were measured according to IPC-TM-650 2.4.18.3. Example 1B and Comparative example were respectively tested 10 times for each of the mechanical properties thereof. Average values are shown in Table 1.

TABLE 1

| | | Example | Comparative |
|---|---|---|---|
| Mechanical property | Unit | 1B | example |
| Tensile Strength | Mpa | 228 | 156 |
| Elongation | % | 27 | 10 |

The results of Table 1 show that the mechanical properties of Example 1B are much better than those of Comparative example. Therefore, the two-layer polyimide shield according to this invention has better mechanical properties and possesses a better shielding ability compared to the conventional shield.

Referring to FIG. 6, the first preferred embodiment of the polyimide shield 3 is attached to a circuitry substrate 61 to form an integrated circuit structure 6. The polyimide shield 3 covers the circuitry substrate 61 and includes the colored film layer 312 opposite to the circuitry substrate 61. A copper foil is most frequently used to form the circuitry substrate 61.

While the present invention has been described in connection with what are considered the most practical and preferred embodiments, it is understood that this invention is not limited to the disclosed embodiments but is intended to cover various arrangements included within the spirit and scope of the broadest interpretation and equivalent arrangements.

What is claimed is:

1. A polyimide shield comprising:
a base film layer made from polyimide; and
a colored film layer overlying the base film layer and containing a coloring agent that is dispersed in a polymer.

2. The polyimide shield of claim 1, wherein the colored film layer has a light transmittance less than 1%.

3. The polyimide shield of claim 1, wherein the polymer is selected from the group consisting of polyimides, aromatic polyamides, aromatic poly(amide-imides), aromatic poly(1,3,4-oxadiazoles), aromatic polyhydrazides, and aromatic polyetherimides.

4. The polyimide shield of claim 1, wherein the polymer is a polyimide.

5. The polyimide shield of claim 1, wherein the weight ratio of the polymer to the coloring agent ranges from 1-10.

6. The polyimide shield of claim 1, wherein the weight ratio of the polymer to the coloring agent ranges from 1.5-8.

7. The polyimide shield of claim 1, wherein the coloring agent is selected from the group consisting of carbon black, titanium oxide, boron nitride, aluminum nitride, and combinations thereof.

8. The polyimide shield of claim 1, wherein the colored film layer has a thickness ranging from 1 μm-3 μm.

9. The polyimide shield of claim 1, wherein the colored film layer has a thickness ranging from 2 μm-2.5 μm.

10. The polyimide shield of claim 1, further comprising an adhesive film layer formed on the base film layer opposite to the colored film layer.

11. The polyimide shield of claim 1, further comprising a release film layer covering the adhesive film layer.

12. A method of making a polyimide shield comprising:
forming a base film layer from polyimide; and
applying a liquid composition onto the base film layer, the liquid composition containing a polymer and a coloring agent that is dispersed in the polymer.

13. The method of claim 12, wherein the polymer is selected from the group consisting of polyamic acid and polyimide.

14. The method of claim 12, wherein the liquid composition has a viscosity of 200 cps-3000 cps.

15. The method of claim 12, wherein the liquid composition has a viscosity of 500 cps-1000 cps.

16. An integrated circuit structure comprising:
a circuitry substrate; and
a polyimide shield covering the circuitry substrate, and including a base film layer that is made from polyimide, and a colored film layer that overlies the base film layer and that contains a coloring agent dispersed in a polymer.

17. The integrated circuit structure of claim 16, wherein the colored film layer has a light transmittance less than 1%.

18. The integrated circuit structure of claim 16, wherein the polymer is polyimide.

19. The integrated circuit structure of claim 16, wherein the coloring agent is selected from the group consisting of carbon black, titanium oxide, boron nitride, aluminum nitride, and combinations thereof.

20. The integrated circuit structure of claim 16, further comprising an adhesive film layer formed between the base film layer and the circuitry substrate.
